(19) United States
(12) Patent Application Publication
(10) Pub. No.: US 2024/0085454 A1
(43) Pub. Date: Mar. 14, 2024

(54) COAXIAL WAFER PROBE AND CORRESPONDING MANUFACTURING METHOD

(71) Applicant: Federal Institute of Metrology METAS, Bern-Wabern (CH)

(72) Inventors: Johannes Hoffmann, Bremgarten (CH); Denis Vasyukov, Basel (CH); Toai Lequang, Bem (CH)

(21) Appl. No.: 17/754,745

(22) PCT Filed: Oct. 8, 2020
(86) PCT No.: PCT/EP2020/078247

§ 371 Date: Apr. 11, 2022

(30) Foreign Application Priority Data
Oct. 9, 2019 (CH) 01288/19

(51) Int. Cl. G01R 1/067; G01R 3/00

(52) U.S. Cl. CPC G01R 1/06705; G01R 1/06738; G01R 1/06744; G01R 1/06761; G01R 1/06772; G01R 3/00

(57) ABSTRACT

A measurement probe for on-wafer testing of semiconductor devices, comprises a plurality of contact fingers at a distal end for contacting landing pads of the wafer. The measurement probe comprises a central conductive wire, the central conductive wire being connected to a first contact finger of the measurement probe, a tapered glass layer over a longitudinal portion of the central conductive wire, and a conductive outer layer coating the glass layer, the conductive outer layer being connected to at least a second contact finger of the measurement probe. For manufacturing such a measurement probe, a glass capillary is heated and drawn over the central conductive wire. A prove holder may comprise such a measurement probe.

### CROSS-REFERENCE TO RELATED APPLICATIONS

This application is a national phase entry under 35 U.S.C. § 371 of International Patent Application PCT/EP2020/078247, filed Oct. 8, 2020, designating the United States of America and published as International Patent Publication WO 2021/069566 A1 on Apr. 15, 2021, which claims the benefit under Article 8 of the Patent Cooperation Treaty to Swiss Patent Application Serial No. 01288/19, filed Oct. 9, 2019.

### TECHNICAL FIELD

The present disclosure relates to a measurement probe for on-wafer testing of semiconductor devices.

### BACKGROUND

U.S. Pat. No. 6,078,184 discloses a measurement probe for contacting planar microwave circuits and includes a substrate with a coplanar line in a housing in which a coaxial line terminal is constructed and from which at least two contact fingers extend. One end of the coplanar line is connected with the coaxial line terminal and the other end is connected with the contact fingers. The contact fingers are constructed as thin needles made of spring steel material, which are arranged alongside one another.

Other forms of measurement probes are also disclosed in U.S. Patent Application Publication Nos. US20030132759, US20020163349 and U.S. Pat. No. 6,118,287.

Such a measurement probe bridges the distance from a proximal end for mechanical securing and standardized electrical contact of the probe, to a distal end configured for contacting landing pads of a wafer. The distal end comprises a plurality of contact fingers, for instance, for contacting the ground-signal-ground pads of an RF circuit under test of the wafer.

The dimension of the contact fingers and their spacing should correspond to the dimension and spacing (the pitch) of the landing pads of the device under test. For manufacturability reasons, in known measurement probes, the dimension of the contact fingers is greater than 25 microns and their spacing greater than 25 to 100 microns.

To match with the decrease in size of the semiconductor features and to provide improved RF performance (less capacitive effect), it would be generally beneficial to provide measurement probes having contact fingers whose dimension and spacing are reduced relative to the dimension and spacing of the known measurement probes.

Advantageously, such measurement probes should be easily manufactured such that they can be provided at reasonable cost.

### BRIEF SUMMARY

The present disclosure aims at addressing, at least partially, those issues. More particularly, the present disclosure aims at proposing a measurement probe, and a probe holder including such a measurement probe that is simple to manufacture, yet that can have contact fingers of very small dimension and spacing, down to 25 microns each and below.

To this effect, one aspect of the present disclosure relates to a measurement probe for on wafer testing of semiconductor devices, the measurement probe having a proximal end for connection to a probe holder and a plurality of contact fingers at a distal end for contacting landing pads of the wafer.

According to the present disclosure, the measurement probe comprises:
a central conductive wire extending between the proximal end and the distal end of the measurement probe and including a longitudinal portion, the central conductive wire being electrically connected, at the distal end, to a first contact finger of the measurement probe;
a tapered glass sheath over the longitudinal portion of the central conductive wire; and
a conductive outer layer coating the tapered glass sheath, the conductive outer layer being electrically connected, at the distal end, to at least one second contact finger of the measurement probe.

According to further non-limitative features of the present disclosure, either taken alone or in any technically feasible combination:
the central conductive wire is made of platinum iridium alloy material;
the conductive outer layer is made of platinum;
the measurement probe comprise a bent portion between the proximal end and the distal end to facilitate contact of the contact fingers with the landing pads;
the first contact finger and the second contact finger are separated by a distance of 25 microns or less, preferably 5 microns or less;
the first and second contact fingers are formed by cut-outs in the central conductive wire, in the conductive outer layer and in the glass sheath;
the transverse length of the first and of the second contact fingers are less than 20 microns, and preferably less than 5 microns;
the central conductive wire has, at the proximal end, a diameter of 50 microns or less, and preferably 30 microns or less;
the central conductive wire has, at the distal end, a diameter of 1 micron or less;
the tapered glass sheath has a maximum diameter of 400 microns or

less;
the conductive outer layer has a thickness between 20 nm and 1000 nm, and preferably between 100 nm and 200 nm; and
the contact fingers respectively comprise contact tips.

The present disclosure also relates to a measurement probe holder including such a measurement probe. The probe holder may comprise a tuning fork, in contact with the measurement probe, for providing a force signal.

Another aspect of the present disclosure relates to a method for manufacturing a measurement probe for on wafer testing of semiconductor devices, the method comprising:
inserting a conductive wire into a central hole of a glass capillary, the conductive wire extending beyond two ends of the glass capillary;
heating and drawing the glass capillary over the conductive wire by pulling apart the two ends to form a tapered glass sheath over the conductive wire;
separating the conductive wire and the glass layer at a separating zone to provide two separated portions, the tapered glass sheath coating a longitudinal portion of a central conductive wire of each separated portion; and
forming a conductive outer layer on at least one of the separated portions to form the measurement probe.

According to further non-limitative features of the present disclosure, either taken alone or in any technically feasible combination:
the heating and drawing step further comprises heating and drawing the conductive wire by pulling apart the two ends to form a tapered conductive wire;
the method further comprises treating a distal end of at least one separated portion to cut out portions of the central conductive wire, the conductive outer layer and the glass sheath to respectively define a first contact finger and at least one second contact finger; and
the method further comprises heating the measurement probe at a given position to bend the probe by gravity.

### BRIEF DESCRIPTION OF THE DRAWINGS

Many other features and advantages of the present disclosure will become apparent from reading the following detailed description, when considered in conjunction with the accompanying drawings, in which:

FIG. 1 represents a test system that can include and benefit from a measurement probe and a probe holder according to the present disclosure;

FIG. 2 represents a detailed view of a probe holder according to the present disclosure;

FIG. 3 represents a measurement probe according to the present disclosure;

FIG. 4 represents an enlarged view of the distal end of a measurement probe according to the present disclosure; and

FIGS. 5A to 5D represent a method of manufacturing a measurement probe according to the present disclosure.

### DETAILED DESCRIPTION

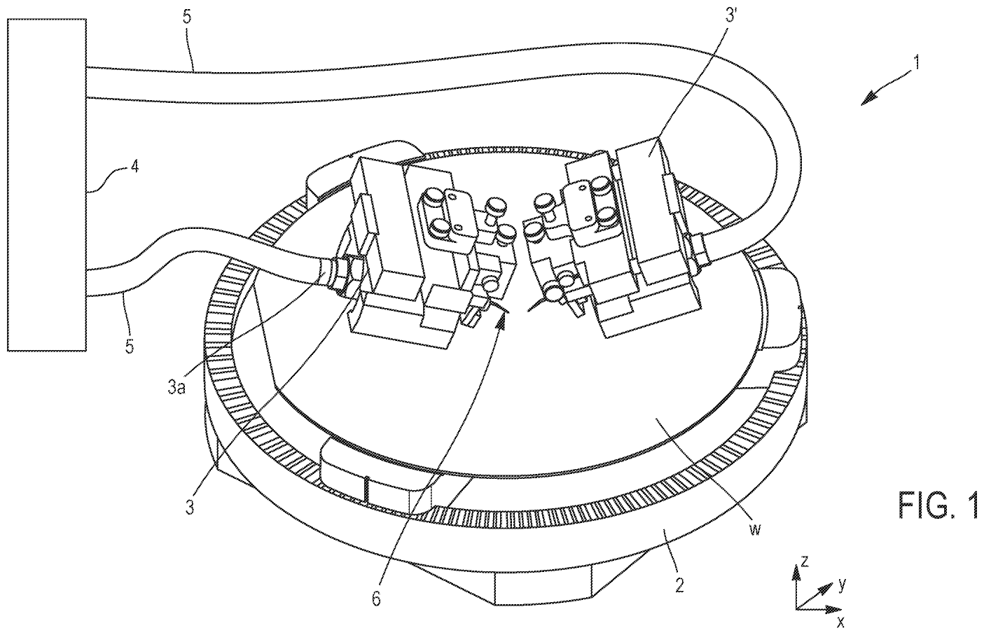

FIG. 1 represents a test system 1 that can include and benefit from the measurement probe and the probe holder according to the present disclosure.

In FIG. 1, a wafer W is disposed on a movable table 2. The table 2 may be moved in the plane along the x and y directions to position selected landing pads of the wafer W at close proximity of contact fingers of the measurement probes. Typically, the table 2 may be moved with a precision of around 1 to 5 microns.

In the example of FIG. 1, the test system 1 is a two-port system and comprises two probe holders 3, 3′ secured at the extremity of two movable arms (not shown in FIG. 1). Each probe holder 3, 3′ can be moved along the x, y, z directions typically over a distance of about 100 microns to multiple hundreds of microns with a great precision of less than one micron down to 10 nm. Each movable arm may comprise one or a plurality of piezo actuators for the very precise displacement of each probe holder 3, 3′.

Each probe holder 3, 3′ is electrically connected, for instance, by a coaxial cable 5, to at least one test unit 4 such as a vector network analyzer.

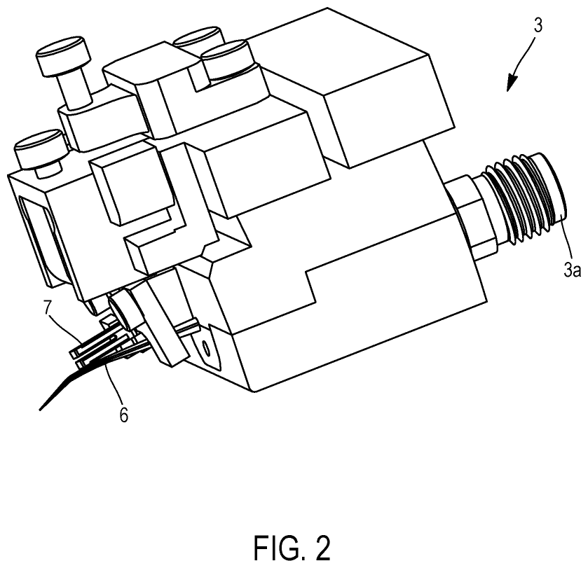

FIG. 2 represents a detailed view of a probe holder 3, 3′ according to the present disclosure. It comprises an electrical connector 3a for connecting the coaxial cable 5 and with mechanical parts to secure the holder 3, 3′ to the movable arms.

A measurement probe 6 has a proximal end 6a conductively secured to the probe holder. The probe holder makes the electrical connection between the probe 6 and the connector 3a, such that electrical signals measured at a distal end 6b of the probe 6 is effectively transmitted to the test unit 4 via the coaxial cable 5.

As this will be described in greater details in a further passage of this description, the measurement probe 6 is advantageously provided, at its distal end, with a plurality of contact fingers, at least for conducting a signal line and a ground line to the test unit 4. Preferably, the measurement probe 6 is provided with three contact fingers to connect to the ground-signal-ground landing pads of an RF device under test disposed on the wafer W.

Advantageously, the probe holder 3, 3′ comprises a tuning fork 7 for providing a force signal allowing to control the height position of the probe. As depicted in FIG. 2, the measurement probe 6 is in contact with one prong of the tuning fork 7, in a contact mode AFM configuration (as described in, for example, U.S. Pat. No. 6,240,771), such that when the distal end of the measurement probe 6 is contacting the wafer surface, the contact force is transmitted to one of the prongs and the resonance frequency of the fork 7 is modified. This shift of resonance frequency and thus the applied force and the contact forces can be measured and monitored.

This arrangement allows to control and limit the contact force of the measurement probe 6 on the wafer by controlling the height position of the probe holder.

Additionally, this arrangement can be used to scan the contact fingers disposed at the distal end of the measurement probe 6 over the wafer region where the contact pads are located. By electrical measurement with the test unit 4, e.g., a vector network analyzer, while scanning, one can identify the electrical properties of the surface of the wafer and the position of the contact pads with an accuracy better than 10 nm compared to roughly 1 micron with optical techniques.

For proceeding to an on-wafer measurement, the test system 1 is operated with a control loop comprising the piezo actuator of the movable arm and the tuning fork 7 as a force sensor. First, the wafer table 2 and the movable arm are brought into a position such that the contact fingers of the measurement probe 6 get close to the landing pads of the wafer W. Then by constant lowering of the probe on the wafer, physical contact is established. The control loop will take over height regulation during landing. The correct x-y position can be either set with optical control for large landing pads or by the tuning fork 7 assisted scan process. Those landing pads may correspond to any input/output of a semiconductor device under test of the wafer W.

Once the measurement probe 6 is contacting the landing pads of the wafer W, the test unit 4 may be operated to provide and capture signals to/from the device under test to effectively test its operation and performance.

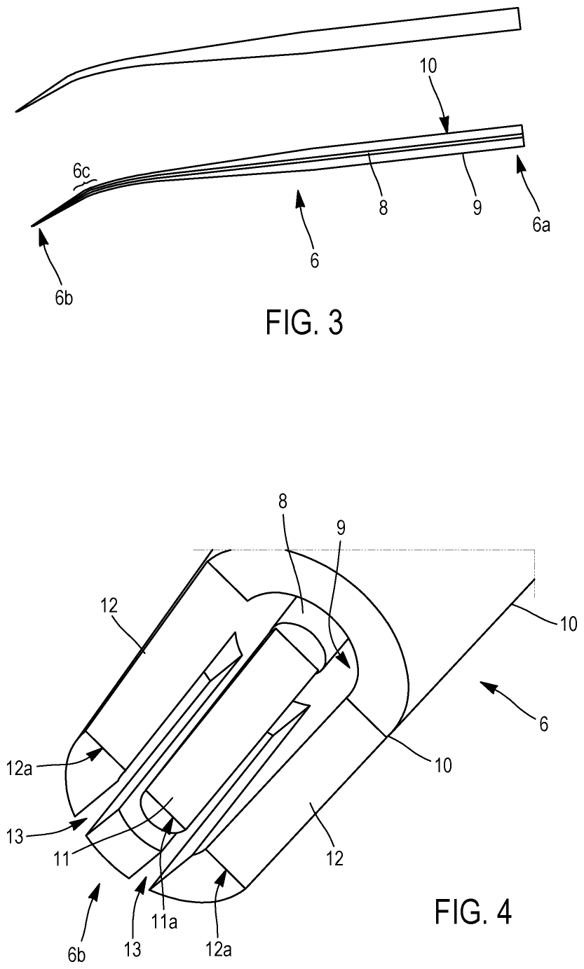

With reference to FIG. 3, a measurement probe 6 according to the present disclosure may include a proximal end 6a for its connection to the probe holder 3, 3′ and a distal end 6b for contacting the wafer W. A plurality of contact fingers is provided at the distal end 6b of the measurement probe 6. The length of the measurement probe 6, from its proximal end 6a to its distal end 6b may be between 100 microns and 10 cm, and typically between 2 cm and 6 cm.

The measurement probe 6 comprises a central electrically conductive wire 8, for instance, made of platinum iridium alloy. The wire 8 extends between the proximal end 6a and the distal end 6b to conduct an electrical signal from the landing pad of the wafer W to the connector 3a. The extremity of the wire 8 at the distal end 6b may form a first contact finger of the measurement probe 6. The central conductive wire 8 may be tapered, i.e., present a diameter that is generally decreasing from the proximal end to the distal end of the measurement probe. The central conductive wire 8 may typically present a diameter of 50 microns or less at, or close to, the proximal end, and preferably less than 30 microns. The central conductive wire 8 may typically present a diameter of 1 micron or less at, or close to, the distal end. The central conductive wire 8 is encapsulated or “coated” with a tapered glass sheath 9. By “coated” it is meant in the present description that the glass material is in direct contact with the central wire 8, and encapsulates completely the wire 8 over a longitudinal portion of it. The sheath 9 is tapered such that the external diameter of the glass sheath 9 is greater at the proximal end of the measurement probe than at its distal end.

In consequence, and generally speaking, the measurement probe 6 has a tapered shape, the dimension of its section decreasing from its proximal end 6a to its distal end 6b. This is due to the thickness of the tapered glass sheath 9 around the wire 8 and the thickness of the wire 8 itself that are varying along the longitudinal portion. These thicknesses are generally decreasing along the longitudinal portion from the side of the proximal end 6a to the side of the distal end 6b. The typical thickness of the tapered glass sheath 9, on the side of the proximal end 6a of the measurement probe 6 may be about 400 microns. On the side of its distal extremity, close to the contact fingers, the thickness of the tapered glass sheath 9 may be less than 100 microns, or 50 microns or even less than 10 microns.

Finally, a measurement probe 6 according to the present disclosure also comprises an electrically conducting outer layer 10. This outer layer 10 is coating the tapered glass sheath 9. The tapered glass sheath 9 is electrically isolating the central conductive wire 8 from the conductive outer layer 10. The combination of the central conductive wire 8, glass sheath 9 and outer conductive layer 10 is forming an electrical transmission line. The conductive outer layer 10 is at the distal end 6b of the measurement probe 6, in electrical contact with at least one second contact finger, and preferably two contact fingers. The conductive outer layer 10 may be made of platinum or of another metal. Its thickness is typically between 20 and 1000 nm, and preferably between 100 and 200 nm.

As this is very apparent in FIG. 3, the measurement probe 6 comprises at least one bent portion 6c, located in this example close to the distal end 6b. This allows facilitating the contact of the contact fingers with the landing pads of the wafer W, as can be seen in FIG. 1.

FIG. 4 represents an enlarged and schematic view of the distal end 6b of the measurement probe 6. In this figure, for better visibility, the thickness of the conductive outer layer 10 has been increased and the thickness of the glass sheath 9 decreased in comparison with their preferred thickness values. The central wire 8 is prolonged with a first contact finger 11 formed from a longitudinal cut-out of the central wire 8. This cut-out defines a first contact edge 11a of the first contact finger 11. A plurality of other cut-outs 13 in the conductive outer layer 10 and glass sheath 9 also define a plurality of second contact fingers 12 each representing a second contact edge 12a. In operation, the contact edges 11a, 12a get into contact with the landing pads of the wafers.

To improve the quality of these contacts, the contact fingers 11, 12 may comprise contact tips, i.e., protuberances formed by attachment or deposition of electrically conductive material at (or close to) the contact edges 11a, 12a.

The dimension of the surface and pitch of the contact fingers may be very small. For instance, the second contact fingers 12 and the first contact finger 11 (as measured from their center) may be separated by a distance of 25 microns or less, and preferably of 5 microns or less. This distance corresponds essentially to the dimension of the external diameter of the glass sheath 9 at the distal end of the measurement probe 6. Similarly, the edges 12a, 11a may present a transverse dimension of less than 20 microns and preferably less than 5 microns. This length corresponds essentially to the diameter of the central conductive wire 8 at the distal end of the measurement probe and to the thickness of the outer layer 10, respectively.

These dimensions, much less than in the prior art measurement probes, present the advantage to be able to contact very small pitch and transverse dimension landing pads. Due to the small dimensions on can measure with very high frequency signals from the test unit 4. Another advantage of the small dimensions is the small capacitance and thus the ability to accurately measure high impedance devices such as e.g., nano wires.

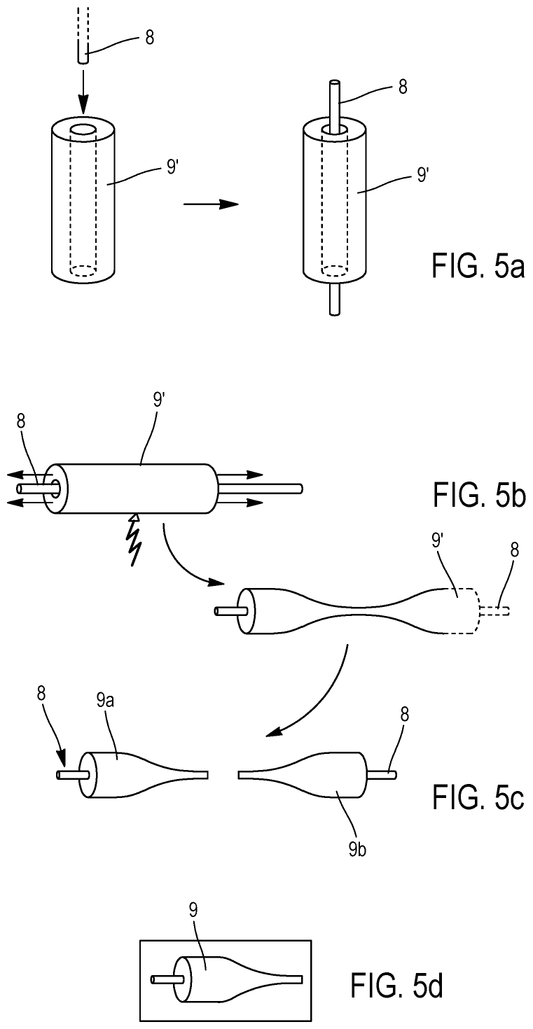

FIGS. 5A to 5D represent a method of manufacturing a measurement probe 6 according to the present disclosure. In a first step shown in FIG. 5A, an electrically conducting wire 8 is inserted into a central hole of a glass capillary 9′. The glass capillary 9′ has two ends, and after the insertion of the wire 8 into the hole, the wire 8 extends beyond the two ends of the capillary 9′.

In a second step shown in FIG. 5B, the glass capillary 9′ is heated, for instance, with a laser, and the two ends of the capillary 9′ are pulled apart from each other. During this step, the glass material of the capillary 9′ becomes softer and the capillary 9′ is drawn over the conductive wire 8. The dimension of the central hole reduces such that the glass material gets into contact with the conductive wire 8 at least in a tapered zone of the capillary 9′ to form a tapered glass sheath.

The heating may be interrupted to solidify the glass material encapsulating the conductive wire 8 and perfect their contact. A further heating and drawing step may then be added that tends to taper the conductive wire 8. During this further step, the glass sheath and the conductive wire are pulled apart at their two ends to form a tapered glass sheath over a tapered conductive wire.

During the heating and drawing step, the two ends are pulled apart until the tapered zone fractures. FIG. 5C illustrates the two separated portions 9a, 9b after the fracturing step of the glass layer and of the wire 8 at the tapered/fracturing zone. At this stage, each portion 9a, 9b comprises a central conductive wire 8 having a longitudinal portion coated with a tapered glass sheath 9 that forms the basis of the measurement probe 6.

In a following step, shown in FIG. 5D, the outer layer 10 of conductive material is formed by deposition onto the separated portion 9a, 9b to provide the overall structure of the measurement probe 6.

To form the contact fingers, the distal end of the separated portion, i.e., on the side of the tapered zone, is treated to form the contact fingers and contact surfaces. The contact fingers are typically formed by FIB (focused ion beam) by cutting-out excess material. Optionally, tips can be grown by FIB or other techniques on or close to the edges 11a, 12a. Another technique is to attach tips to the edges 11a, 12a. In all cases, the contact edges 11a, 12a are electrically connected to the central conductive wire 8 and to the conductive outer layer 10, respectively.

To form the bent portion 6c, the measurement probe 6, after the deposition step of the outer layer or just before this deposition step, is positioned horizontally and heated, for instance, by a laser at the level of the bent zone. By the combined effect of gravity and the softening of the glass material, the probe bends and the bent zone is created.

Other variations to the disclosed embodiments can be understood and effected by those skilled in the art in practicing the claimed invention, from a study of the drawings, the specification, and the accompanying claims.

1. A measurement probe for on-wafer testing of semiconductor devices, the measurement probe having a proximal end for connection to a probe holder and a plurality of contact fingers at a distal end for contacting landing pads of the wafer, the measurement probe further comprising:
a central conductive wire extending between the proximal end and the distal end of the measurement probe and including a longitudinal portion, the central conductive wire being electrically connected, at the distal end, to a first contact finger of the measurement probe;
a tapered glass sheath over the longitudinal portion of the central conductive wire; and
a conductive outer layer coating the tapered glass sheath, the conductive outer layer being electrically connected, at the distal end, to at least one second contact finger of the measurement probe.

2. The measurement probe of to claim 1, wherein the central conductive wire comprises a platinum iridium alloy.

3. The measurement probe of claim 1, wherein the conductive outer layer comprises platinum.

4. The measurement probe of claim 1, further comprising a bent portion between the proximal end and the distal end to facilitate contact of the contact fingers with the landing pads.

5. The measurement probe of claim 1, wherein the first contact finger and the second contact finger are separated by a distance of 25 microns or less.

6. The measurement probe of claim 1, wherein the first and second contact fingers are formed by cut-outs in the central conductive wire, in the conductive outer layer and in the glass sheath.

7. The measurement probe of claim 1, wherein a transverse length of the first and of the second contact fingers are less than 20 microns.

8. The measurement probe of claim 1, wherein the central conductive wire has, at the proximal end, a diameter of 50 microns or less.

9. The measurement probe of claim 1, wherein the central conductive wire has, at the distal end, a diameter of 1 micron or less.

10. The measurement probe of claim 1, wherein the tapered glass sheath has a maximum diameter of 400 microns or less.

11. The measurement probe of claim 1, wherein the contact fingers respectively comprise contact tips.

12. The measurement probe of claim 1, wherein the conductive outer layer has a thickness between 20 nm and 1000 nm.

13. A method for manufacturing a measurement probe for on-wafer testing of semiconductor devices, the method comprising:
inserting a conductive wire into a central hole of a glass capillary, the conductive wire extending beyond two ends of the glass capillary;
heating and drawing the glass capillary over the conductive wire by pulling apart the two ends to form a tapered glass sheath over the conductive wire;
separating the conductive wire and the glass sheath at a separating zone to provide two separated portions, the tapered glass sheath coating a longitudinal portion of a central conductive wire of each separated portion; and
forming a conductive outer layer on at least one of the separated portions to form the measurement probe.

14. The method of claim 13, wherein the heating and drawing of the glass capillary over the conductive wire further comprises heating and drawing the conductive wire by pulling apart the two ends to form a tapered conductive wire.

15. The method of claim 13, further comprising treating a distal end of the at least one separated portion to cut out portions of the central conductive wire, the conductive outer layer, and of the glass sheath to respectively define a first contact finger and at least one second contact finger.

16. The method of claim 13 further comprising heating the measurement probe at a position to bend the probe by gravity.

17. A measurement probe holder for on-wafer testing of semiconductor devices, comprising a measurement probe according to claim 1.

18. The measurement probe holder of claim 17, wherein the probe holder comprises a tuning fork in contact with the measurement probe for providing a force signal.

19. The measurement probe of claim 7, wherein a transverse length of the first and of the second contact fingers are less than 5 microns.

20. The measurement probe of claim 8, wherein the central conductive wire has, at the proximal end, a diameter of 30 microns or less.
